(19) United States
(12) Patent Application Publication
(10) Pub. No.: US 2026/0354227 A1
(43) Pub. Date: Nov. 5, 2026

(54) EMBEDDED TRACE SUBSTRATE WITH WETTABLE FLANKS

(71) Applicant: TEXAS INSTRUMENTS INCORPORATED, Dallas, TX (US)

(72) Inventors: Chun Ping LO, Allen, TX (US); Jovenic Romero ESQUEJO, Baguio City (PH); Vivek ARORA, San Jose, CA (US)

(21) Appl. No.: 19/195,509

(22) Filed: Apr. 30, 2025

(51) Int. Cl. H10W 70/65; H05K 1/181; H10W 70/05; H10W 70/66; H10W 70/68; H10W 70/685; H10W 72/00; H10W 74/10; H10W 90/00

(52) U.S. Cl. CPC H10W 70/65; H10W 70/05; H10W 70/095; H10W 70/66; H10W 70/68; H10W 70/685; H05K 1/181; H10W 72/0198; H10W 74/10; H10W 90/401; H10W 90/724

(57) ABSTRACT

In examples, a semiconductor package includes a substrate including multiple metal layers and multiple pre-preg layers in between the multiple metal layers. The multiple metal layers include a metal layer that comprises a conductive terminal having bottom and lateral surfaces, the lateral surface of the conductive terminal flush with a lateral surface of the substrate, and the conductive terminal including a cavity exposed to the bottom and lateral surfaces of the conductive terminal. The package includes a semiconductor die attached to the substrate, and a mold compound over the semiconductor die and the substrate.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such integrated circuits on a wafer is called fabrication. After wafer fabrication, the wafer is cut into multiple pieces, called semiconductor dies, with each die containing one or more of the integrated circuits. The cutting, or sawing, of the wafer into individual dies is called singulation. An individual die may then be attached to a substrate or die attach pad. The resulting structure is subsequently covered with a mold compound to produce a package.

### SUMMARY

In examples, a semiconductor package includes a substrate including multiple metal layers and multiple pre-preg layers in between the multiple metal layers. The multiple metal layers include a metal layer that comprises a conductive terminal having bottom and lateral surfaces, the lateral surface of the conductive terminal flush with a lateral surface of the substrate, and the conductive terminal including a cavity exposed to the bottom and lateral surfaces of the conductive terminal. The package includes a semiconductor die attached to the substrate, and a mold compound over the semiconductor die and the substrate.

In examples, a method for manufacturing a semiconductor package includes forming a substrate by iteratively: plating a metal layer; applying a pre-preg layer on the metal layer; and forming a via through the pre-preg layer, the substrate including a bottom pre-preg layer and a bottom metal layer, the bottom metal layer on a bottom surface of the substrate and contacting the bottom pre-preg layer. The method includes laser drilling a first cavity extending partially through the bottom metal layer; attaching a semiconductor die to the substrate; covering the substrate and the semiconductor die with a mold compound; and singulating the substrate through the first cavity to form a semiconductor package and a second cavity exposed to bottom and lateral surfaces of the semiconductor package.

### BRIEF DESCRIPTION OF THE DRAWINGS

FIGS. 1A, 1B, 1C, 1D, 1E, 1F, 1G, 1H, 1I, and 1J are cross-sectional, bottom-up, profile, perspective, bottom-up, profile, perspective, bottom-up, profile, and perspective views, respectively, of a semiconductor package including an embedded trace substrate (ETS) with wettable flanks, in accordance with various examples.

FIGS. 2A, 2B, and 2C are cross-sectional, top-down, and perspective views, respectively, of a semiconductor package including an ETS with wettable flanks soldered to a surface, in accordance with various examples.

FIG. 3 is a flow diagram of a method for manufacturing a semiconductor package including an ETS with wettable flanks, in accordance with various examples.

FIGS. 4A, 4B, 4C, 4D, 4E, 4F, 4G, 4H, 4I, 4J, 4K, 4L, 4M, 4N, 4O, 4P, and 4Q are a process flow of a method for manufacturing a semiconductor package including an ETS with wettable flanks, in accordance with various examples.

FIG. 5 is a block diagram of an electronic device comprising a semiconductor package including an ETS with wettable flanks, in accordance with various examples.

### DETAILED DESCRIPTION

Wettable flanks in semiconductor packaging refer to cavities formed on the bottom and lateral surfaces of semiconductor package conductive terminals. These cavities are plated with a solderable finish. Such cavities are typically applied to lead frame-based packages such as quad flat no-lead (QFN) or dual flat no-lead (DFN) devices. When the package is attached to a surface using solder, such as to a printed circuit board (PCB), the solder fills the cavity and extends outside the cavity in a pattern that is visible from above, in a top-down view. The wettable flank enables optical or automated inspection systems to verify the quality of the solder joint during surface-mount assembly by providing a visible and solder-wettable region on the side of the conductive terminal. This facilitates in-line inspection processes and helps ensure robust mechanical and electrical connectivity between the package and the PCB. Wettable flanks may be produced through selective plating or etching processes during lead frame preparation and package assembly. Wettable flanks are compatible with a range of surface finishes including nickel palladium gold and nickel silver. The presence of wettable flanks enhances solder joint inspectability, supports automotive-grade reliability standards, and aids in the detection of insufficient solder or non-wet conditions.

Embedded trace substrates (ETSs) are a type of organic, laminate-based substrate used in advanced semiconductor packaging, especially for small form-factor and high-density applications. ETSs are manufactured using a process in which metal traces, typically copper, are embedded within a dielectric layer rather than being patterned on a substrate surface. This is achieved through sequential lamination processes, laser drilling of vias, and semi-additive or modified semi-additive patterning of metal layers. ETS technology allows for finer line widths and spaces, improved electrical performance due to reduced conductor loss, and reduced warpage from improved layer symmetry. The embedded architecture enables routing of signals with lower inductance and shorter path lengths, supporting high-speed digital and radio frequency applications. ETSs are useful in system-in-package (SiP) modules, advanced mobile processors, and other applications requiring high input/output density and compact form factors.

Despite the utility of ETSs, wettable flanks are not presently available in ETSs. This limitation can impact manufacturing quality control, particularly in applications (e.g., automotive) requiring in-line verification of solder joint integrity. The absence of wettable flanks necessitates alternative inspection methods such as X-ray imaging or electrical continuity testing, which may introduce additional process complexity or inspection time and which increases manufacturing costs. Furthermore, the lack of visible solder joint formation on the terminal sides can limit the compatibility of the package with certain automotive or high-reliability standards that require verifiable solder joints.

This description presents various examples of a semiconductor package that includes an ETS having wettable flanks. Examples of a manufacturing process for forming wettable flanks in ETSs are described, as are the semiconductor packages produced by such manufacturing processes. In examples, multiple ETSs are produced in bulk through an iterative process, with consecutive ETSs sharing conductive terminals. A laser drill is used to form a cavity having a truncated cone shape (i.e., a three-dimensional cone shape with the apex of the cone replaced by a flat, horizontal surface) in the shared conductive terminals, and a saw is subsequently used to perform a singulation process, including by sawing through the cavity of the conductive terminal, thereby forming individual ETSs having wettable flanks. The ETSs may be included as part of a semiconductor package and may subsequently be attached to a surface, such as a PCB, using solder. The solder fills the wettable flanks, forming solder fillets that are readily visible in a top-down view and conferring the numerous technical advantages of wettable flanks described above.

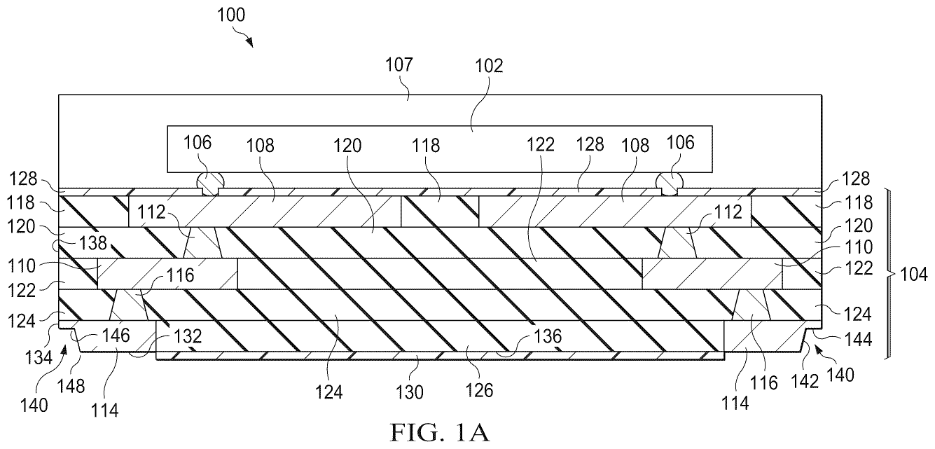

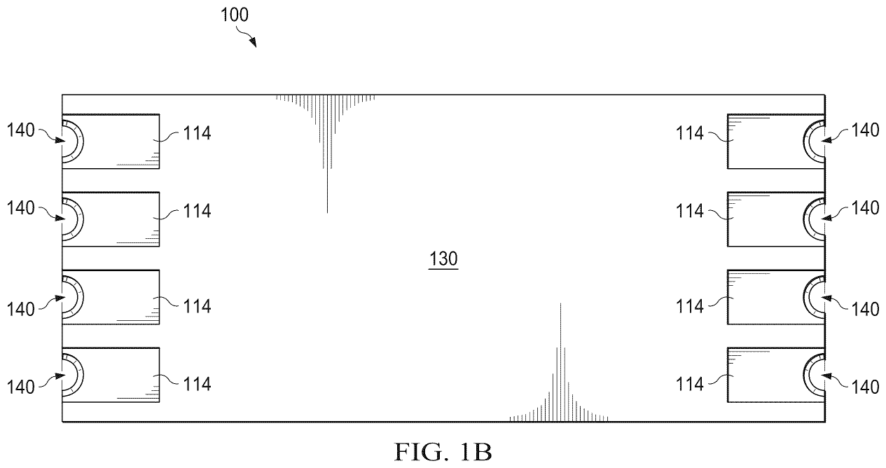

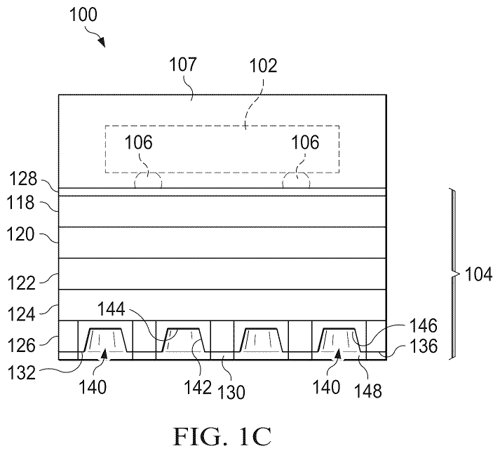

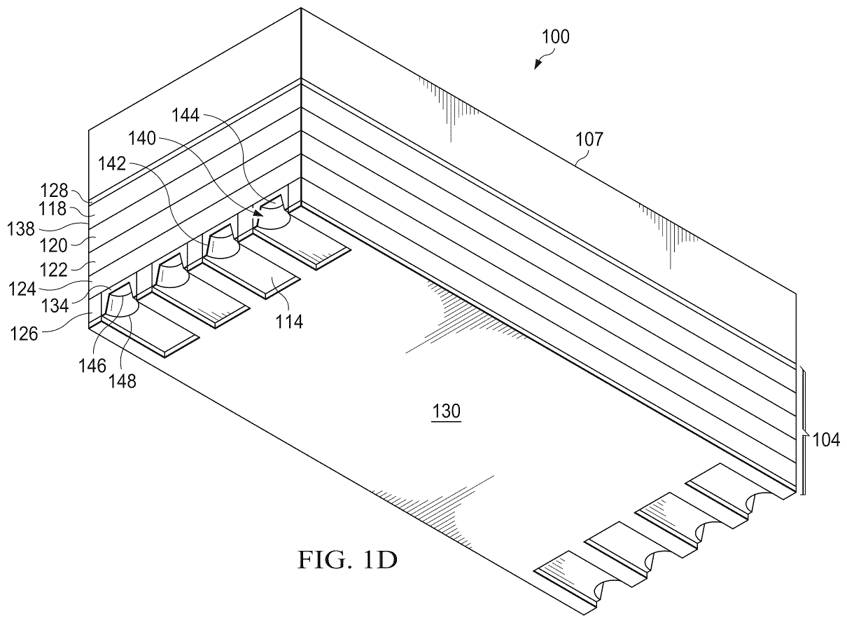

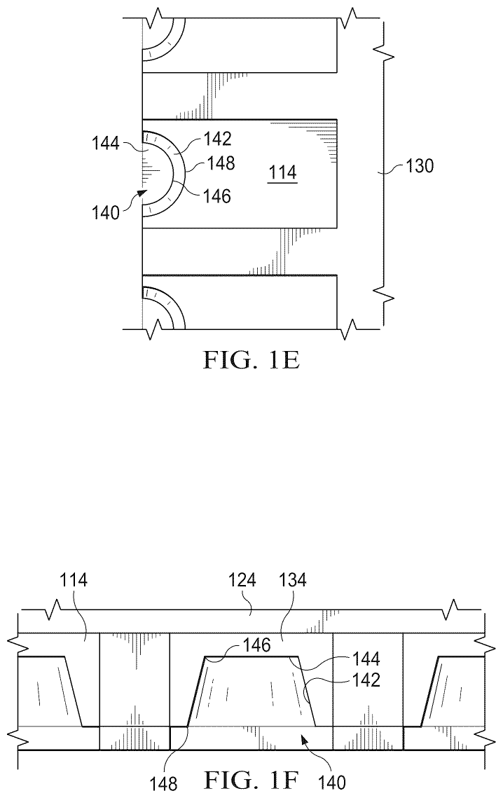

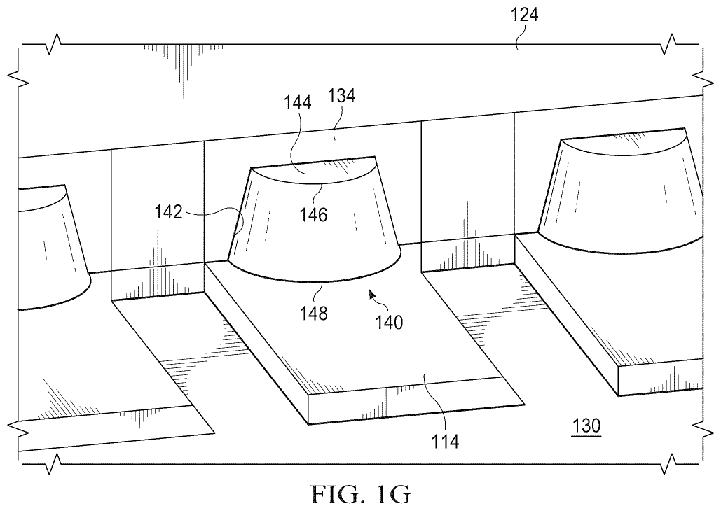

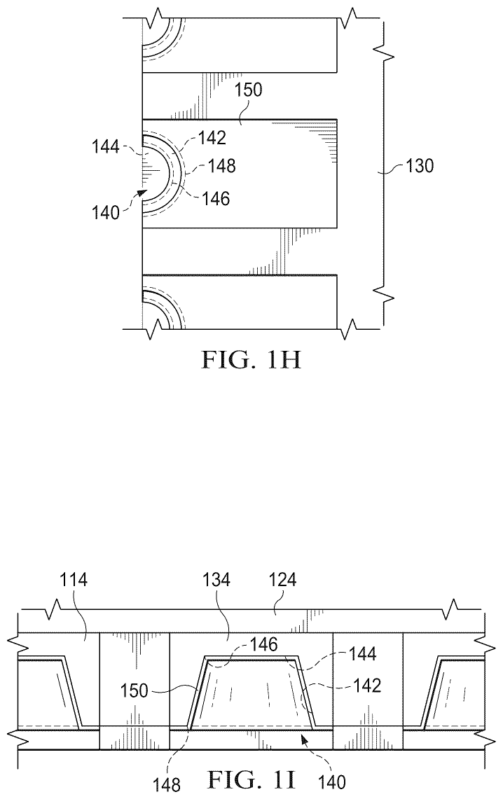

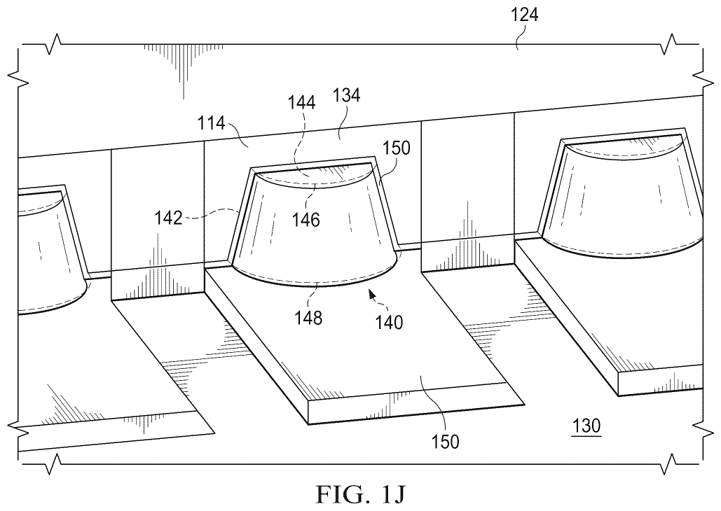

FIGS. 1A, 1B, 1C, 1D, 1E, 1F, 1G, 1H, 1I, and 1J are cross-sectional, bottom-up, profile, perspective, bottom-up, profile, perspective, bottom-up, profile, and perspective views, respectively, of a semiconductor package including an ETS with wettable flanks, in accordance with various examples. More particularly, FIGS. 1A-1D show a semiconductor package 100, such as a QFN package, including a semiconductor die 102 attached to a substrate 104 by solder bumps 106. A mold compound 107 covers and contacts the semiconductor die 102, the substrate 104, and the solder bumps 106. In examples, the substrate 104 is an ETS, although the scope of this disclosure includes a variety of substrate types. The substrate 104 may include a metal layer 108 attached to the solder bumps 106, and a metal layer 110 attached to the metal layer 108 by vias 112. The substrate 104 also may include conductive terminals 114 attached to the metal layer 110 by vias 116. The metal layers 108, 110, the vias 112, 116, and the conductive terminals 114 may include any suitable metal or metal alloy, such as copper. Other materials, such as electroplated and/or finishing materials (e.g., nickel gold; electroless nickel, electroless palladium, immersion gold (ENEPIG); organic solderability preservative (OSP)) may be included as well.

The substrate 104 also may include multiple layers of dielectric material. For example, the substrate 104 includes a dielectric layer 118 that is horizontally coplanar with the metal layer 108, and a dielectric layer 120 that is horizontally coplanar with the vias 112. The substrate 104 may include a dielectric layer 122 that is horizontally coplanar with the metal layer 110, and a dielectric layer 124 that is horizontally coplanar with the vias 116. The substrate 104 may include a dielectric layer 126 that is horizontally coplanar with the conductive terminals 114. In some examples, the dielectric layers 118, 120, 122, 124, and 126 are pre-preg, although in other examples, other materials may be useful, such as AJINOMOTO® build-up film (ABF).

The substrate 104 may include solder masks to isolate and protect the various layers of the substrate 104. For example, the substrate 104 may include a solder mask 128 on a top side of the substrate 104 (i.e., contacting the metal layer 108 and the dielectric layer 118). The substrate 104 may also include a solder mask 130 on a bottom side of the substrate 104 (i.e., contacting the dielectric layer 126). Various solder mask configurations are contemplated and included in the scope of this description.

The vias 112, 116 appear to have a trapezoidal shape in the cross-sectional view. In the perspective view, the vias 112, 116 have a truncated cone shape. In some cases, this description may refer to cavities as having specific shapes, such as trapezoids, truncated cones, and/or half truncated cones. Such descriptions of cavity shapes are intended to convey that the shapes and sizes of the structure(s) surrounding the cavity define cavity contours that have a trapezoidal shape, a truncated cone shape, and/or a half truncated cone shape.

The vias 112, 116 have trapezoidal and truncated cone shapes in the cross-sectional and perspective views, respectively, due to the laser drilling technique used to form the vias 112, 116. Laser drilling produces trapezoidal/truncated cone shapes because the laser beam naturally tapers as the beam moves through the material. The laser beam is wider at the surface where the beam enters the structure being drilled and narrows as the beam penetrates deeper, removing more material at the top than at the bottom. This forms an opening with a wider diameter at the top and a narrower diameter at the bottom, forming a trapezoidal and/or truncated cone shape instead of a cylinder. In FIG. 1A, the vias 112, 116 may appear to be narrower at the top and wider at the bottom, but this is because the substrate 104 may be manufactured upside-down relative to the orientation shown in FIG. 1A.

The conductive terminals 114 have similar physical features, and thus one of the conductive terminals 114 is now described as a representative example. The conductive terminal 114 includes a bottom surface 132 and a lateral surface 134. The bottom surface 132 is approximately flush with a bottom surface 136 of the dielectric layer 126, as shown. Similarly, the lateral surface 134 is approximately flush with a lateral surface 138 of the remainder of the substrate 104, as shown. The conductive terminal 114 includes a cavity 140. The cavity 140 is exposed to the bottom surface 132 and the lateral surface 134, meaning that openings to the cavity 140 are coplanar with the bottom surface 132 and the lateral surface 134.

FIGS. 1E-1G provide detailed bottom-up, profile, and perspective views, respectively, of the cavity 140. Referring now to FIGS. 1A-1G, the shape of the cavity 140 is defined by contours of the conductive terminal 114. In particular, the conductive terminal 114 has a curved portion 142 (which appears as a sloped, straight surface in the cross-sectional view of FIG. 1A) and a flat portion 144. The flat portion 144 is parallel to the bottom surface 132. The curved portion 142 and the flat portion 144 intersect along an edge 146. The edge 146 is curved, for example, as a semicircle. The curved portion 142 and the bottom surface 132 intersect along an edge 148. The edge 148 is curved, for example, as a semicircle. The length of the edge 148 is greater than the length of the edge 146. The resulting shape of the cavity 140, as defined by the contours of the conductive terminal 114, is that of part (e.g., half) of a truncated cone in the perspective view, and as that of part (e.g., half) of a trapezoid in the cross-sectional view.

In some examples, portions of the conductive terminal 114 may be electroplated and/or finished with specific metals or metal alloys. For example, FIGS. 1H-1J are bottom-up, profile, and perspective views of the conductive terminal 114, and more specifically, of the cavity 140. The conductive terminal 114, including the cavity 140, are covered by a metal 150. This metal 150 may comprise a metal or metal alloy. For example, the metal 150 may comprise electrolytic nickel gold, ENEPIG, or OSP. The metal 150 may facilitate solder wetting and protect the conductive terminal 114 from deleterious processes, such as oxidation. In some examples, multiple metals and/or alloys cover the conductive terminal 114, and with respect to such examples, the metal 150 represents two or more such metals and/or alloys. The areas of the conductive terminal 114 covered by the metal 150 depend on when the metal 150 is applied. If the metal 150 is applied prior to singulation of the conductive terminal 114 (as described below), the metal 150 covers the bottom surface 132 and the surfaces of the cavity 140, but not the lateral surface 134. If the metal 150 is applied post-singulation of the conductive terminal 114 (as described below), the metal 150 covers the bottom surface 132, the surfaces of the cavity 140, and the lateral surface 134.

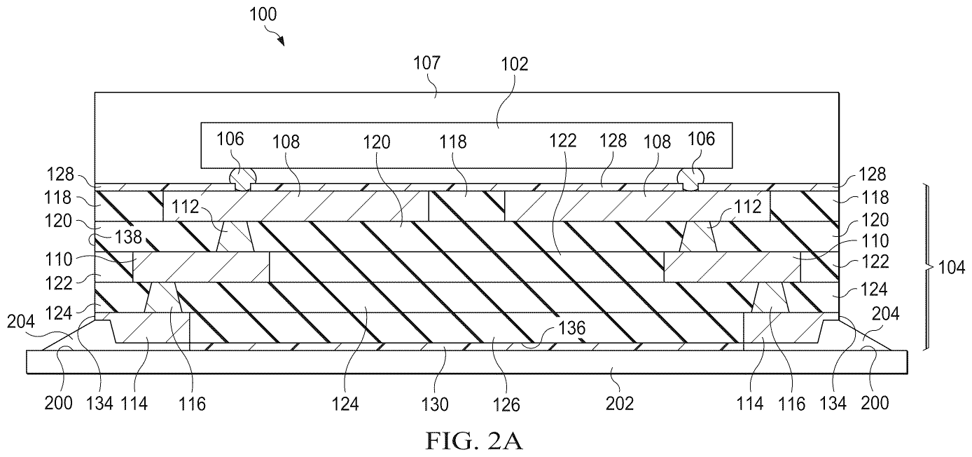

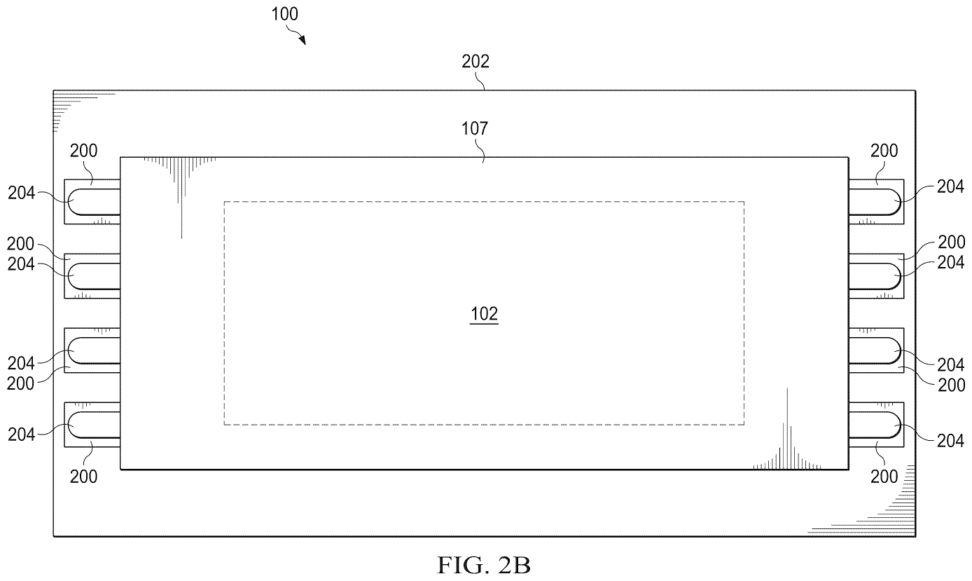

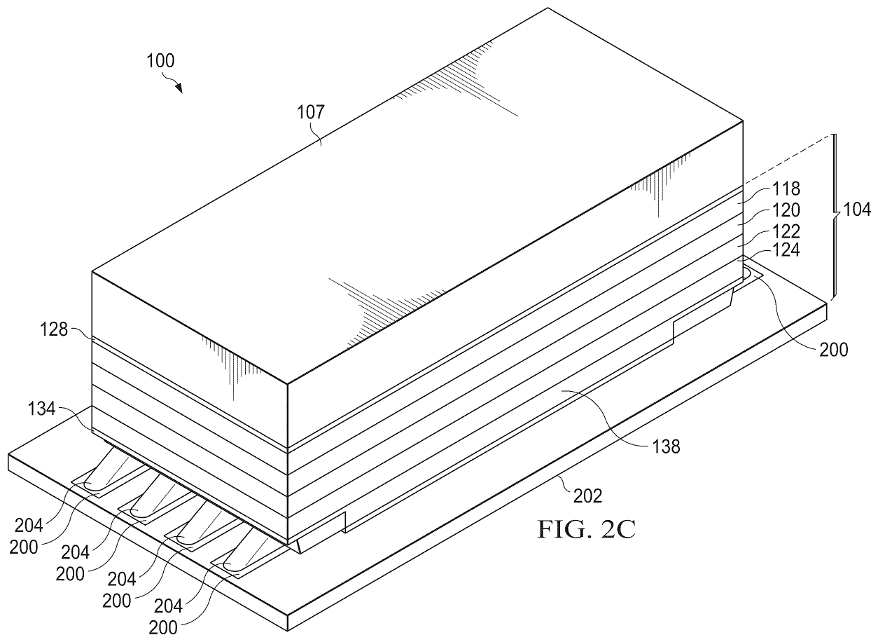

FIGS. 2A, 2B, and 2C are cross-sectional, top-down, and perspective views, respectively, of a semiconductor package including an ETS with wettable flanks soldered to a surface, in accordance with various examples. In particular, FIGS. 2A-2C show the semiconductor package 100 attached to surfaces, such as conductive surfaces 200 on a PCB 202. Solder fillets 204 attach the conductive terminals 114 to the conductive surfaces 200. The top-down view of FIG. 2B shows the ease with which the solder fillets 204 may be optically inspected from above, serving as verification whether each conductive terminal 114 has been properly soldered to a respective conductive surface 200.

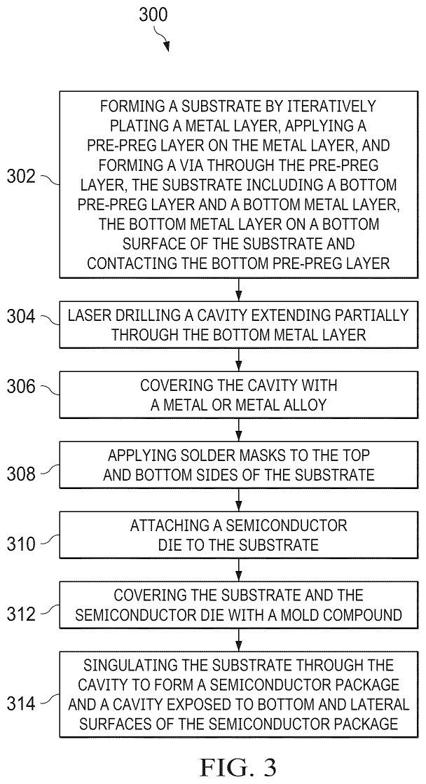

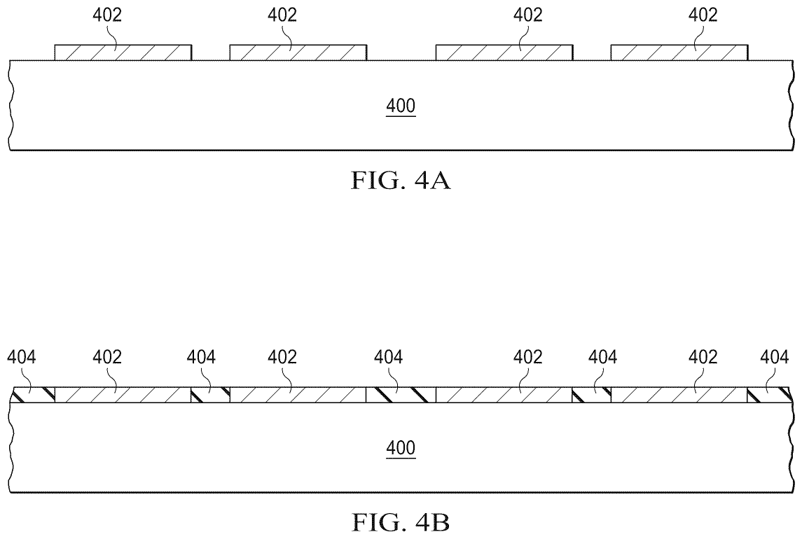

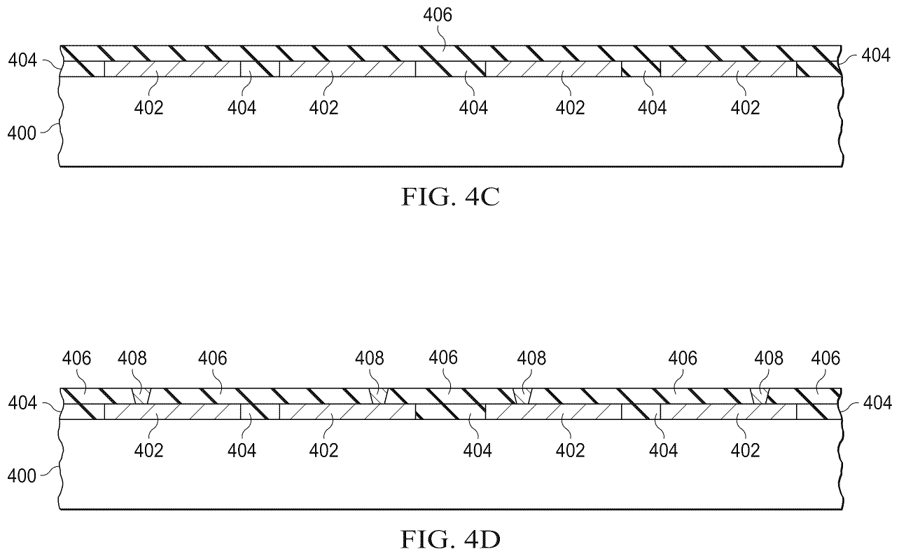

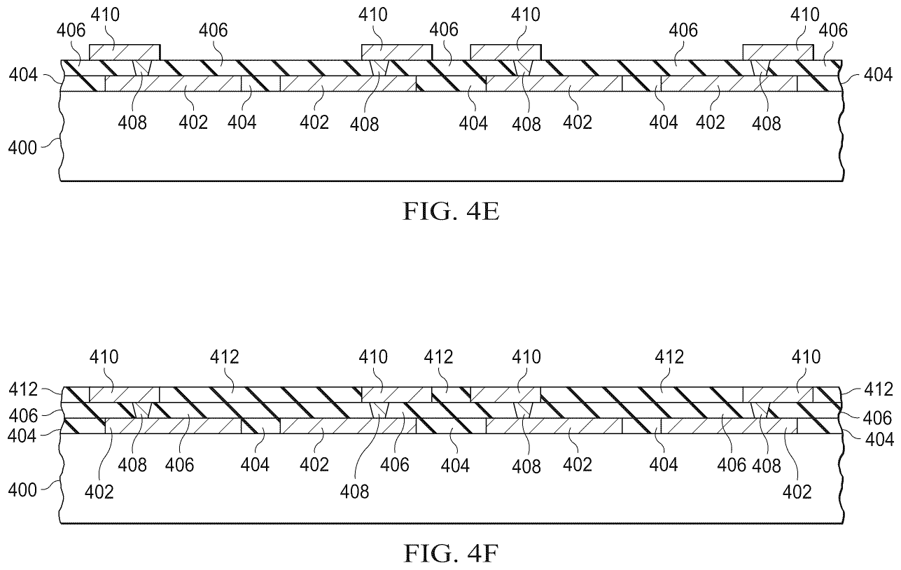

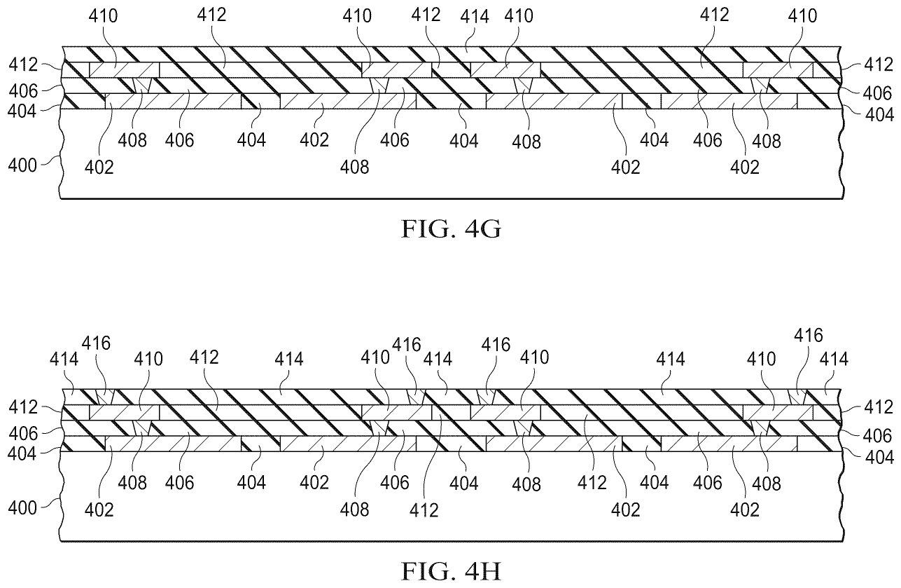

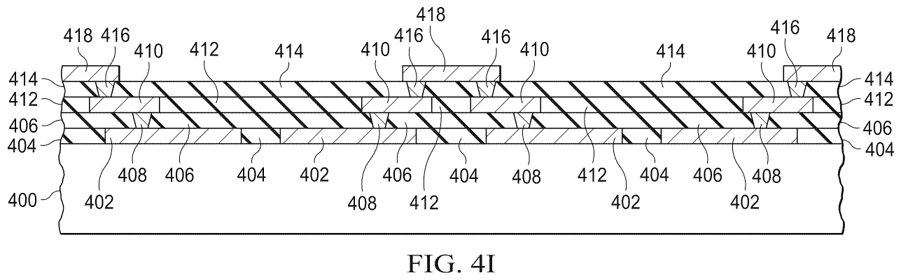

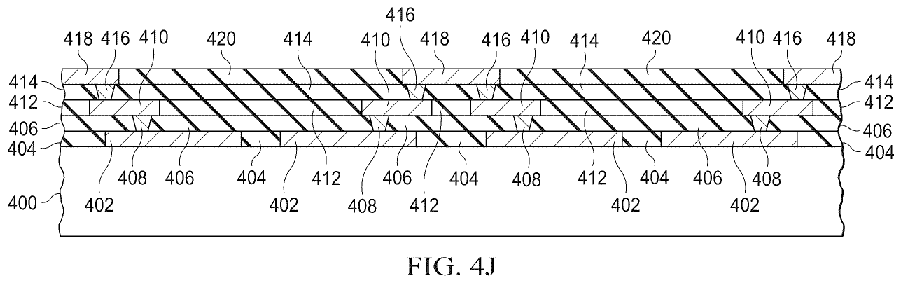

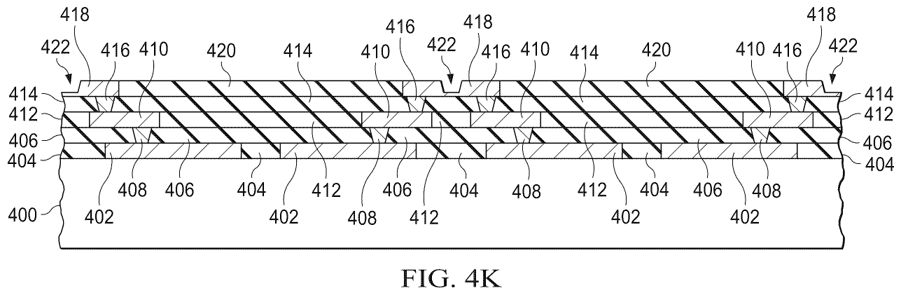

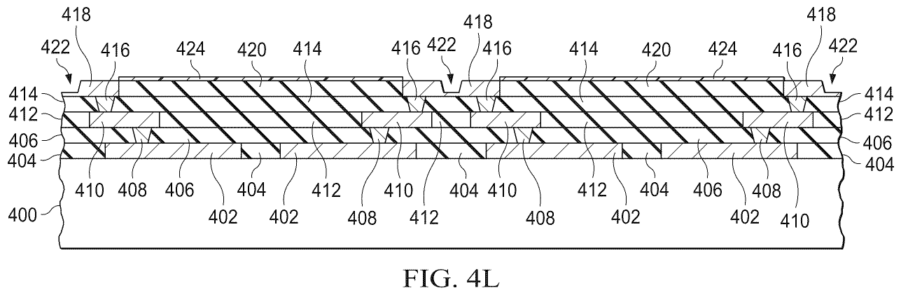

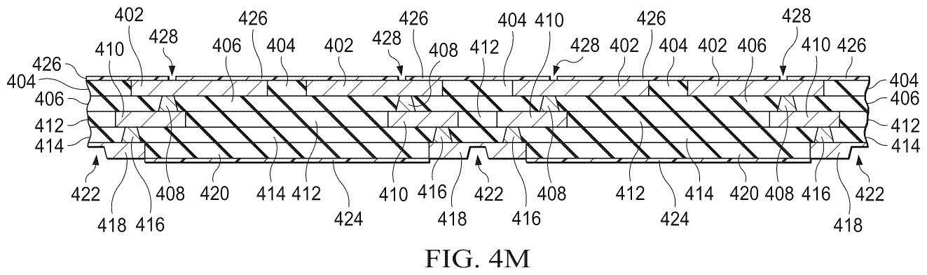

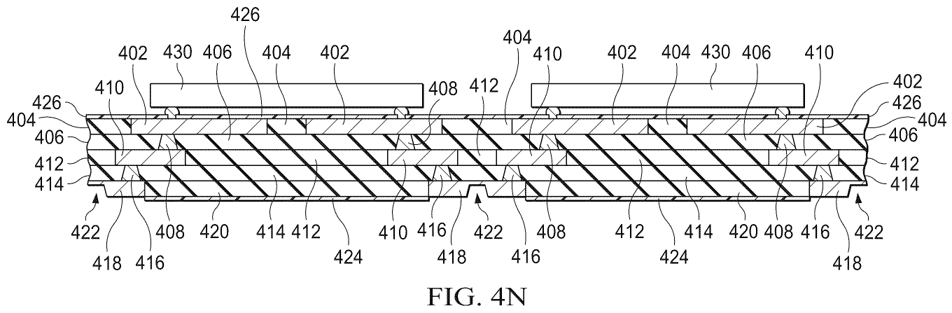

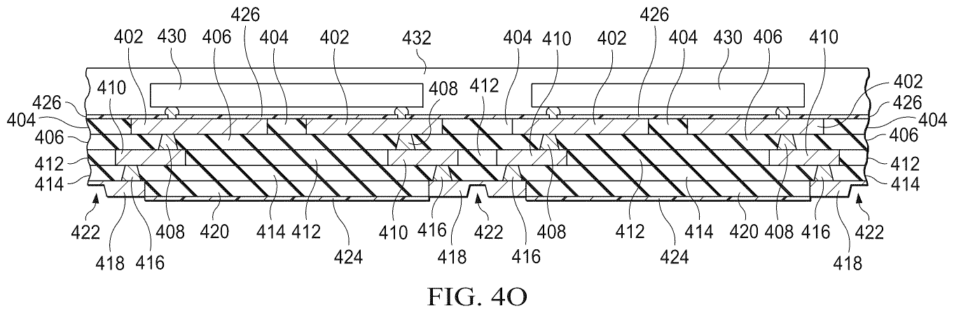

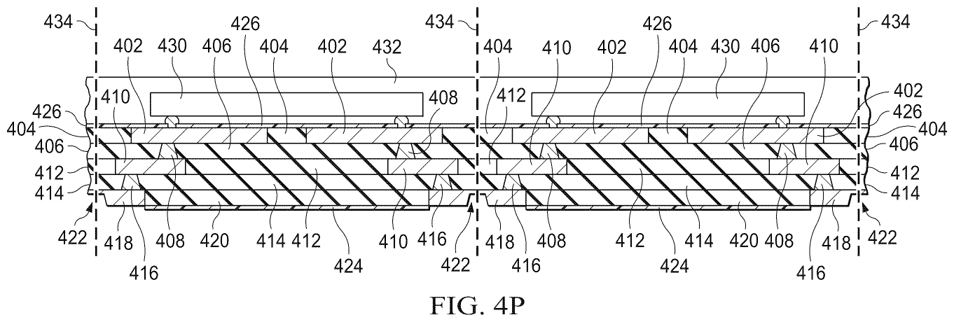

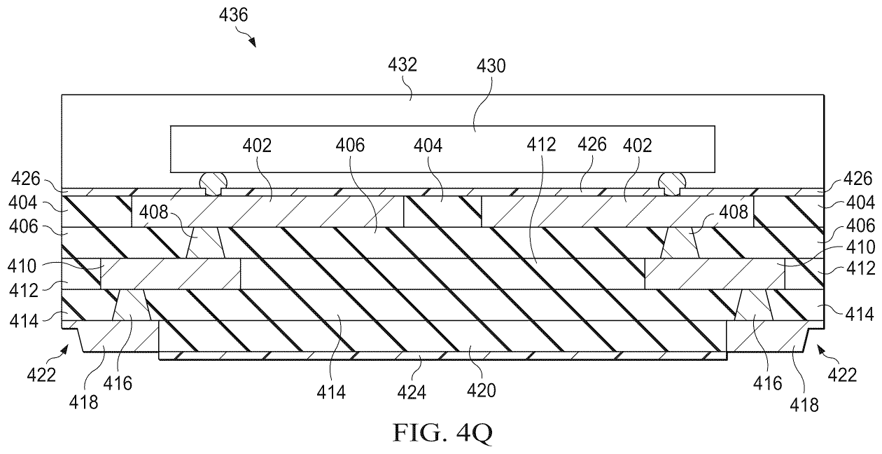

FIG. 3 is a flow diagram of a method 300 for manufacturing a semiconductor package including an ETS with wettable flanks, in accordance with various examples. FIGS. 4A, 4B, 4C, 4D, 4E, 4F, 4G, 4H, 4I, 4J, 4K, 4L, 4M, 4N, 4O, 4P, and 4Q are a process flow of a method for manufacturing a semiconductor package including an ETS with wettable flanks, in accordance with various examples. Accordingly, FIGS. 3 and 4A-4Q are now described in parallel with each other.

The method 300 includes forming a substrate (e.g., an ETS) by iteratively plating a metal layer, applying a pre-preg layer on the metal layer, and forming a via through the pre-preg layer (302). The substrate includes a bottom pre-preg layer and a bottom metal layer (302). The bottom metal layer is on a bottom surface of the substrate and contacts the bottom pre-preg layer (302). FIG. 4A shows a carrier 400 and a metal layer 402 electroplated on the carrier 400. To electroplate the metal layer 402 on the carrier 400, a seed layer (e.g., copper seed layer) may be applied on the carrier 400, a photoresist layer may be formed on the seed layer, photolithography techniques (e.g., using a suitably patterned mask(s), light exposure, application of developer solution) may be useful to pattern the photoresist layer, the metal layer 402 may be electroplated using the seed layer and the patterned photoresist layer, the photoresist layer may be stripped away, and the remaining seed layer may be etched away, thereby leaving the metal layer 402 as shown in FIG. 4A. FIG. 4B depicts the structure of FIG. 4A, but with a dielectric layer 404 applied in the same horizontal plane as the metal layer 402. FIG. 4C depicts the structure of FIG. 4B, but with a dielectric layer 406 formed on the metal layer 402 and the dielectric layer 404. FIG. 4D shows the structure of FIG. 4C, except that vias 408 are formed in the dielectric layer 406. The vias 408 may be formed by laser drilling, deposition of a seed layer (e.g., using suitable photolithography techniques), and electroplating the vias 408. FIG. 4E shows the structure of FIG. 4D, except that a metal layer 410 is formed on the dielectric layer 406 and contacting the vias 408. The metal layer 410 may be formed in the same or similar manner as the metal layer 402, described above. FIG. 4F is identical to FIG. 4E, except that a dielectric layer 412 is applied in the same horizontal plane as the metal layer 410. FIG. 4G shows the same structure as FIG. 4F, except that a dielectric layer 414 is applied on the metal layer 410 and on the dielectric layer 412. FIG. 4H shows the same structure as FIG. 4G, except that vias 416 are formed in the dielectric layer 414. The vias 416 may be formed using the same technique as that used to form the vias 408, described above. FIG. 4I is identical to FIG. 4H, except that a metal layer 418 is formed on the dielectric layer 414 and contacting the vias 416. FIG. 4J is identical to FIG. 4I, except that a dielectric layer 420 is formed to be horizontally coplanar with the metal layer 418.

The dielectric layers 404, 406, 412, 414, and 420 may comprise pre-preg, although other materials, such as ABF, are contemplated and included in the scope of this description.

The method 300 includes laser drilling a cavity extending partially through the bottom metal layer (304). FIG. 4K depicts the structure of FIG. 4J, except that cavities 422 are laser drilled into the metal layer 418, as shown. The laser drilling causes the cavities 422 to have a trapezoidal shape in the cross-sectional view and a truncated cone shape in the perspective view. The cavities 422 at the far left and right ends in FIG. 4K are depicted as half trapezoids because FIG. 4K is intended to be a limited view of the structure being manufactured, and not necessarily because these cavities 422 are any different from the cavity 422 shown in the center of FIG. 4K. The depth of the laser drilling is controlled such that the cavities 422 do not completely extend through a thickness of the metal layer 418.

Optionally, the method 300 includes covering the cavity with a metal or metal alloy (306). For example, the metal 150 may be applied, as described above.

The method 300 includes applying solder masks to the top and bottom sides of the substrate (308). FIG. 4L is identical to FIG. 4K, except that a solder mask 424 is applied to the bottom surface of the substrate. FIG. 4M is identical to FIG. 4L, except that a solder mask 426 is applied to the top surface of the substrate. The solder mask 426 may be formed to include solder joint openings 428.

The method 300 includes attaching a semiconductor die to the substrate (310), covering the substrate and the semiconductor die with a mold compound (312), and singulating the substrate through the cavity to form a semiconductor package and a cavity exposed to bottom and lateral surfaces of the semiconductor package (314). FIG. 4N is identical to FIG. 4M, except that semiconductor dies 430 are attached to the metal layer 402 through the solder joint openings 428. FIG. 4O is identical to FIG. 4N, except that a mold compound 432 is applied to the semiconductor dies 430 and the solder mask 426. FIG. 4P is identical to FIG. 4O, except that the structure is singulated (e.g., by mechanical saw) along lines 434, which extend through the cavities 422. FIG. 4Q shows an individual semiconductor package 436, post-singulation. The semiconductor package 436 is representative of the semiconductor package 100, described above.

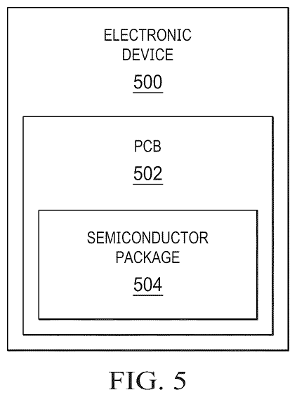

FIG. 5 is a block diagram of an electronic device comprising a semiconductor package including an ETS with wettable flanks, in accordance with various examples. More specifically, FIG. 5 shows an electronic device 500 including a printed circuit board (PCB) 502 and a semiconductor package 504 attached to the PCB 502. Examples of the electronic device 500 may include a smartphone, a tablet, a laptop computer, a desktop computer, a television, a wireless audio device (e.g., headphones), a video game console, a wireless Internet device, a drone, a sensor, an aircraft, a space craft, a road vehicle, a home appliance, etc. The semiconductor package 504 may comprise the semiconductor package 100 and/or the semiconductor package 436, described above. The semiconductor package 504 may have any suitable form, such as a QFN package.

In this description, the term “attach” may cover connections, communications, or signal paths that enable a functional relationship consistent with this description. For example, if device A generates a signal to control device B to perform an action: (a) in a first example, device A is attached to device B by direct connection; or (b) in a second example, device A is attached to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “conductive terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a substrate including multiple metal layers and multiple pre-preg layers in between the multiple metal layers, the multiple metal layers including a metal layer that comprises a conductive terminal having bottom and lateral surfaces, the lateral surface of the conductive terminal flush with a lateral surface of the substrate, the conductive terminal including a cavity exposed to the bottom and lateral surfaces of the conductive terminal;
a semiconductor die attached to the substrate; and
a mold compound over the semiconductor die and the substrate.

2. The semiconductor package of claim 1, wherein an edge of the cavity forms a semicircle on the bottom surface of the conductive terminal.

3. The semiconductor package of claim 1, wherein the cavity is a half trapezoid in a cross-sectional view of the conductive terminal.

4. The semiconductor package of claim 1, wherein the cavity has a half truncated cone shape.

5. The semiconductor package of claim 1, wherein the cavity includes a curved portion and a flat portion, the flat portion parallel with the bottom surface of the conductive terminal, the curved portion intersecting the flat portion along a semicircle within the cavity.

6. The semiconductor package of claim 1, wherein the cavity includes at least one of nickel, palladium, gold, silver, and tin.

7. The semiconductor package of claim 1, wherein the cavity includes electroless nickel electroless palladium immersion gold (ENEPIG).

8. The semiconductor package of claim 1, wherein the cavity includes organic solderability preservative (OSP).

9. A semiconductor package, comprising:
a substrate including multiple metal layers and multiple pre-preg layers contacting the multiple metal layers, the substrate having a conductive terminal on bottom and lateral surfaces of the substrate, the conductive terminal having a cavity exposed to bottom and lateral surfaces of the conductive terminal, the cavity having a curved portion and a flat portion, the flat portion parallel with the bottom surface of the conductive terminal and intersecting the curved portion along a semicircle within the cavity.

10. The semiconductor package of claim 9, wherein the cavity has the curved portion in a perspective view.

11. The semiconductor package of claim 9, wherein the cavity has the flat portion in a cross-sectional view.

12. The semiconductor package of claim 9, wherein the semicircle is a first semicircle, and wherein an edge of the curved portion forms a second semicircle on the bottom surface of the conductive terminal.

13. The semiconductor package of claim 12, wherein the second semicircle has a greater length than that of the first semicircle.

14. The semiconductor package of claim 9, wherein the cavity has a half truncated cone shape.

15. The semiconductor package of claim 9, wherein the cavity includes at least one of nickel, palladium, gold, silver, and tin.

16. The semiconductor package of claim 9, wherein the cavity includes electroless nickel electroless palladium immersion gold (ENEPIG).

17. The semiconductor package of claim 9, wherein the cavity includes organic solderability preservative (OSP).

18. A method for manufacturing a semiconductor package, comprising:
forming a substrate by iteratively:
plating a metal layer;
applying a pre-preg layer on the metal layer; and
forming a via through the pre-preg layer, the substrate including a bottom pre-preg layer and a bottom metal layer, the bottom metal layer on a bottom surface of the substrate and contacting the bottom pre-preg layer;
laser drilling a first cavity extending partially through the bottom metal layer;
attaching a semiconductor die to the substrate;
covering the substrate and the semiconductor die with a mold compound; and
singulating the substrate through the first cavity to form a semiconductor package and a second cavity exposed to bottom and lateral surfaces of the semiconductor package.

19. The method of claim 18, further comprising covering the first cavity with a metal or metal alloy.

20. The method of claim 18, wherein the second cavity has a trapezoidal cross-section.

21. The method of claim 18, wherein the first cavity has a truncated cone shape.

22. The method of claim 18, further comprising applying electroless nickel, electroless palladium, immersion gold (ENEPIG) inside the first cavity.

23. The method of claim 18, further comprising applying organic solderability preservative (OSP) inside the first cavity.
